(19) United States
(12) Patent Application Publication
(10) Pub. No.: US 2025/0201467 A1
(43) Pub. Date: Jun. 19, 2025

(54) INDUCTOR

(71) Applicant: STMicroelectronics International N.V., Geneva (CH)

(72) Inventors: Ophelie FOISSEY, LA TERRASSE (FR); Frederic GIANESELLO, Saint Jeoire Prieuré (FR)

(21) Appl. No.: 18/977,383

(22) Filed: Dec. 11, 2024

(30) Foreign Application Priority Data
Dec. 18, 2023 (FR) FR2314372

(51) Int. Cl. H01F 27/28

(52) U.S. Cl. CPC H01F 27/2804; H01F 2027/2809

(57) ABSTRACT

The present description provides an inductor arranged in a stack of insulating and conductive levels. An exemplary inductor includes: in a first area of a stack, at least first and second turns respectively arranged in two distinct conductive levels of the stack; and in a second area of the stack, at least third and fourth turns respectively arranged in two distinct conductive levels of the stack, in which the first, second, third, and fourth turns are series-connected between first and second ends of the inductor, so that a current applied between the first and second ends of the inductor flows in a first rotation direction in the first and second turns and in a second rotation direction opposite to the first direction in the third and fourth turns.

### CROSS REFERENCE TO RELATED APPLICATION(S)

This application claims the priority benefit of French Patent Application Number FR2314372, filed on Dec. 18, 2023, entitled “Inductance”, which is hereby incorporated by reference to the maximum extent allowable by law.

### TECHNICAL FIELD

The present disclosure generally concerns integrated electronic circuits and more particularly an inductor structure formed on a substrate.

### BACKGROUND

An induction coil or inductor is an electronic component comprising one or a plurality of conductive loops or turns series-connected between two connection terminals, also called ends of the inductor. The inductance value, expressed in Henry, represents the ability of the inductor to store energy in the form of a magnetic field when an electric current flows therethrough. The inductance value is all the higher as the number of turns of the inductor is high.

In microelectronics, the turns of an induction coil are materialized by conductive tracks in a stack of conductive and insulating levels coating a substrate.

The magnetic field generated by an inductor may cause unwanted couplings with neighboring electronic components. To limit this phenomenon, a planar eight-shaped inductor configuration, enabling to decrease the magnetic field seen by neighboring components, has been provided. This solution however requires a relatively significant surface area.

There thus exists a need to design compact inductors having configurations enabling to decrease the parasitic mutual inductance, that is, the coupling with other devices, while having a significant self-inductance.

### BRIEF SUMMARY

For this purpose, an embodiment provides an inductor arranged in a stack of insulating and conductive levels, comprising:
in a first area of the stack, at least a first and a second turn respectively arranged in two distinct conductive levels of the stack; and
in a second area of the stack, at least a third and a fourth turns respectively arranged in two distinct conductive levels of the stack,
   wherein the first, second, third, and fourth turns are series-connected between a first and a second ends of the inductor, so that a current applied between the first and second ends of the inductor flows in a first rotation direction in the first and second turns and in a second rotation direction opposite to the first direction in the third and fourth turns.

According to an embodiment, the first and the fourth turns are in a same first conductive level and the second and the third turns are in a same second conductive level, the first and second conductive levels being distinct.

According to an embodiment, the second turn and the third turn are adjacent and define together an eight-shaped conductive track.

According to an embodiment, the first, second, third, and fourth turns are series-connected, in this order, between the first and second ends of the inductor.

According to an embodiment, the first end of the inductor is connected to a first connection terminal of the inductor by at least one conductive track located in a third conductive level.

According to an embodiment, the first connection terminal of the inductor is arranged in the first conductive level.

According to an embodiment, the second end of the inductor is connected to a second connection terminal of the inductor by at least one conductive track located in a third conductive level.

According to an embodiment, the second connection terminal of the inductor is arranged in the first conductive level.

According to an embodiment, the midpoint of the inductor is connected to a third connection terminal of the inductor by at least one conductive track located in a third conductive level.

According to an embodiment, the third connection terminal of the inductor is arranged in the first conductive level.

According to an embodiment, the first and second turns are stacked, and the third and fourth turns are stacked.

Another embodiment provides an integrated circuit, comprising at least one inductor such as defined above.

Another embodiment provides a voltage-controlled oscillator, comprising at least one inductor such as defined hereabove.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows, in top view, conductive tracks of an example of an inductor according to an embodiment;

FIG. 2 is a simplified three-dimensional view of the stack of the conductive tracks of the inductor of FIG. 1;

FIG. 3 is a simplified view of a cross-section of the inductor of FIG. 1 along axis A1 of FIGS. 1 and 2; and

FIG. 4 shows a simplified view of a cross-section of the inductor of FIG. 1 along axis A2 of FIGS. 1 and 2.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the methods of manufacturing the described inductors have not been detailed, the described embodiments being compatible with usual inductor manufacturing methods of microelectronics or such methods being within the abilities of those skilled in the art based on the indications of the present description.

Unless indicated otherwise, when reference is made to two elements connected together, this signifies a direct connection without any intermediate elements other than conductors, and when reference is made to two elements coupled together, this signifies that these two elements can b connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

In the rest of the description, inductors formed in a circuit comprising a stack of insulating and conductive levels coating a substrate is considered. Other electronic components may also be integrated in the circuit and connected to the inductor by conductive tracks of the stack. There is here called conductive level a set of conductive tracks defined in a same layer of a conductive material, for example a metal, for example copper. A turn of an inductor corresponds to one or a plurality of conductive tracks, of a same conductive level or of different conductive levels, connected to one another so as to be electrically equivalent to a single loop-shaped track.

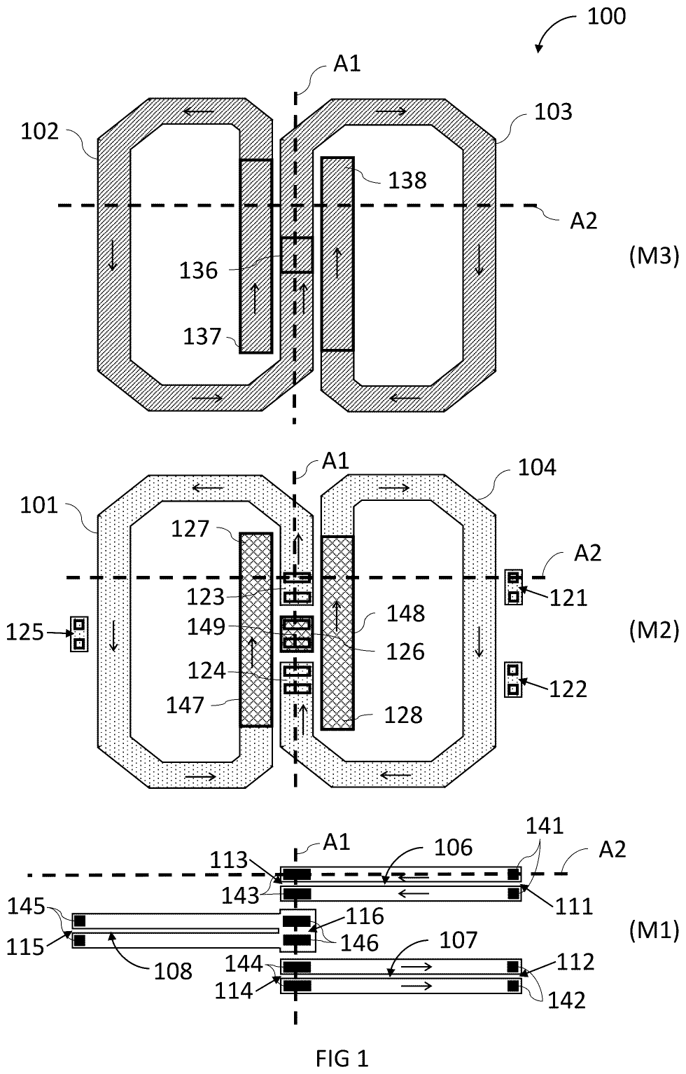

FIG. 1 schematically shows, in top view, conductive tracks of an example of an inductor 100 according to an example of an embodiment.

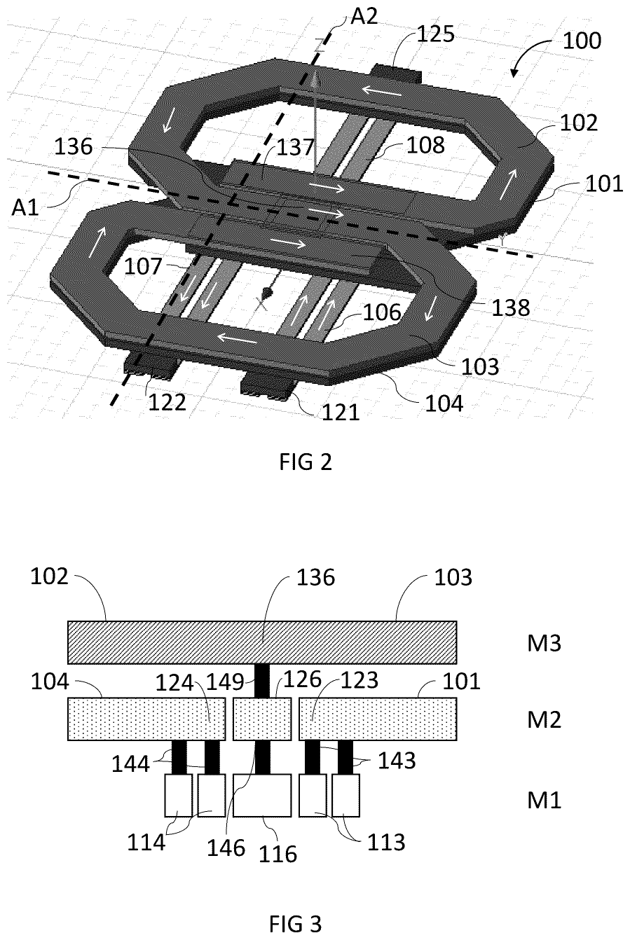

FIG. 2 is a simplified three-dimensional view of the stack of the conductive tracks of the inductor 100 of FIG. 1.

FIG. 3 is a simplified view of a cross-section of the inductor 100 of FIG. 1 along axis A1 of FIGS. 1 and 2.

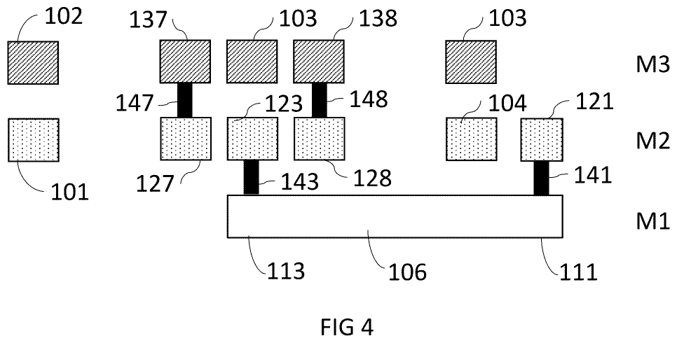

FIG. 4 shows a simplified view of a cross-section of the inductor 100 of FIG. 1 along axis A2 of FIGS. 1 and 2.

In the example of FIGS. 1 to 4, inductor 100 is formed in a stack comprising, in this order from the upper surface of a substrate (not shown in the drawings), three conductive levels M1, M2, M3. The substrate is for example made of a semiconductor material, for example silicon, or of a dielectric material, for example glass. The conductive levels are separated two by two by electrically-insulating layers, for example made of silicon oxide, in which are formed conductive vias, for example metallic, for example made of copper, enabling to electrically connect to one another conductive tracks of levels M1, M2, M3.

FIG. 1 comprises three views (M1), (M2), (M3) respectively showing the conductive tracks of the inductor formed in level M1, the conductive tracks of the inductor formed in level M2, and the conductive tracks of the inductor formed in level M3.

In this example, inductor 100 comprises four turns 101, 102, 103, 104.

Level M2 comprises turns 101 and 104 of the inductor, and level M3 comprises turns 102 and 103 of the inductor.

Turns 101 and 102 are stacked and mainly arranged in a first area of the stack. By stacked turns, there is here meant that, viewed in the layer stacking direction, that is, in a direction orthogonal to the substrate, the conductive tracks forming the turns overlap. In other words, in projection along the layer stacking direction, the conductive tracks forming the turns coincide over substantially their entire surface. As a variant, turns 101 and 102 only partially overlap. In another variant, turns 101 and 102 do not overlap.

Turns 103 and 104 are also stacked and mainly arranged in a second area of the stack, distinct from the first area. As a variant, turns 103 and 104 only partially overlap. In another variant, turns 103 and 104 do not overlap.

There is meant by area of the stack a volume extending over a plurality of levels of the stack, and by two distinct areas there is meant two mostly separate volumes. In other words, turns 103 and 104 are not stacked on turns 101 and 102, that is, they do not cover turns 101 and 102.

In the example of FIGS. 1 to 4, turns 101, 102, 103, and 104 are series-connected, in this order, between a first end 123 and a second end 124 of the inductor.

Turns 101 to 104 are connected so that an electric current propagating from end 123 to end 124 of the inductor first flows through the first turn 101 in a first rotation direction, for example the counterclockwise direction, then through the second turn 102 in the same first rotation direction, then through the third turn 103 in a second rotation direction opposite to the first direction, for example the clockwise direction, then through the fourth turn 104 in the same second rotation direction. The flowing direction of the electric current through inductor 100 is shown by arrows in FIGS. 1 and 2.

In the example of FIGS. 1 to 4, turn 101 is formed by a conductive track entirely formed in level M2 and comprises a first end corresponding to the end 123 of the inductor, and a second end 127. Turn 102 is formed by a conductive track entirely formed in level M3 and comprises a first end 137 and a second end 136. Turn 103 is formed by a conductive track entirely formed in level M3 and comprises a first end corresponding to the end 136 of wire 102, and a second end 138. Turn 104 is formed by a conductive track entirely formed in level M2 and comprises a first end 128 and a second end 124 corresponding to the second end of the inductor.

In the example of FIGS. 1 to 4, the inductor comprises one or a plurality of conductive vias 147 extending in the insulating level separating levels M2 and M3 and electrically connecting the second end 127 of the first turn 101 to the first end 137 of the second turn 102. More particularly, in this example, vias 147 are in contact, by their lower surface, with the upper surface of end 127 of turn 101, and, by their upper surface, with the lower surface of end 137 of turn 102.

In the example shown in FIGS. 1 to 4, the inductor further comprises one or a plurality of conductive vias 148 extending in the insulating level separating levels M2 and M3 and electrically connecting the second end 138 of the third turn 103 to the first end 128 of the fourth turn 104. More particularly, in this example, vias 148 are in contact, by their lower surface, with the upper surface of the end 128 of turn 104, and, by their upper surface, with the lower surface of the end 138 of turn 103.

In this example, inductor 100 comprises three terminals 121, 122, and 125 of connection to an external circuit. In the shown example, connection terminals 121, 122, 125 are formed in level M2.

The first terminal 121 is connected to the first end 123 of the inductor by at least one conductive track 106 of level M1. Track 106 comprises a first end 111 and a second end 113. One or a plurality of conductive vias 141 extend in the insulating level separating levels M1 and M2 and electrically connect the first end 111 of track 106 to terminal 121. More particularly, in this example, vias 141 are in contact, by their lower surface, with the upper surface of end 111 of track 106, and, by their upper surface, with the lower surface of terminal 121. Further, one or a plurality of conductive vias 143 extend in the insulating level separating levels M1 and M2 and electrically connect the second end 113 of track 106 to the first end 123 of the inductor. More particularly, in this example, vias 143 are in contact, by their lower surface, with the upper surface of end 113 of track 106, and, by their upper surface, with the lower surface of end 123 of the inductor.

The second terminal 122 is connected to the second end 124 of the inductor by at least one conductive track 107 of level M1. Track 107 comprises a first end 112 and a second end 114. One or a plurality of conductive vias 142 extend in the insulating level separating levels M1 and M2 and electrically connect the first end 112 of track 107 to terminal 122. More particularly, in this example, vias 142 are in contact, by their lower surface, with the upper surface of the end 112 of track 107, and, by their upper surface, with the lower surface of terminal 122. Further, one or a plurality of conductive vias 142 extend in the insulating level separating levels M1 and M2 and electrically connect the second end 114 of track 107 to the second end 124 of the inductor. More particularly, in this example, vias 144 are in contact, by their lower surface, with the upper surface of end 114 of track 107, and, by their upper surface, with the lower surface of end 124 of the inductor.

The third terminal 125 is connected to the common end 136 of turns 102 and 103, defining the midpoint of the inductor, by at least one conductive track 126 of level M2 and at least one conductive track 108 of level M1. Terminal 125 enables, for certain applications, to use the inductor in a differential mode. Track 108 comprises a first end 115 and a second end 116. One or a plurality of conductive vias 145 extend in the insulating level separating levels M1 and M2 and electrically connect the first end 115 of track 108 to terminal 125. More particularly, in this example, vias 145 are in contact, by their lower surface, with the upper surface of the end 115 of track 108, and, by their upper surface, with the lower surface of terminal 125. Further, one or a plurality of conductive vias 146 extend in the insulating level separating levels M1 and M2 and electrically connect the second end 116 of track 108 to a conductive track 126 of level M2, located vertically in line with the midpoint 136 of the inductor. More particularly, in this example, vias 146 are in contact, by their lower surface, with the upper surface of the end 116 of track 108, and, by their upper surface, with the lower surface of track 126. Further, one or a plurality of conductive vias 149 extend in the insulating level separating levels M2 and M3 and electrically connect track 126 to the midpoint 136 of the inductor. More particularly, in this example, vias 149 are in contact, by their lower surface, with the upper surface of track 126, and, by their upper surface, with the lower surface of midpoint 136.

It should be noted that in the shown example, the inductor comprises, in level M1, two conductive tracks 106 connected in parallel between terminal 121 and end 123 of the inductor. Further, in this example, the inductor comprises, in level M1, two conductive tracks 107 connected in parallel between terminal 122 and end 124 of the inductor. Further, in this example, the inductor comprises, in level M1, two conductive tracks 108 connected in parallel between terminal 125 and the midpoint 136 of the inductor. However, the described embodiments are not limited to this specific case. As a variant, conductive tracks 106, 107, and/or 108 may be simple tracks, or each comprise a number of parallel tracks greater than two.

The path followed by an electric current between the end terminal 121 and the end terminal 122 of the inductor is for example the following.

The electric current flows into inductor 100 via connection terminal 121, flows through via(s) 141, and then through conductive track 106, from its end 111 to its end 113. The current then flows through via(s) 143. The current then flows through the first turn 101 of the inductor from its end 123 to its end 127. The current then flows through via(s) 147. The current then flows through the second turn 102 of the inductor from its end 137 to its end 136, and then through the third turn 103 of the inductor from its end 136 to its end 138. The current then flows through via(s) 148, and then through the fourth turn 104 of the inductor from its end 128 to its end 124. The current then flows through via(s) 144 and conductive track 107, from its end 114 to its end 112. The current then flows through via(s) 142 and comes out of inductor 100 via connection terminal 122.

According to one embodiment, the second turn 102 and the third turn 103 are joined and together define an eight-shaped conductive track. The first end 123 and the second end 124 of the inductor are for example in level M2, for example partially overlapping a central region of the eight-shaped conductive track. The first end 123 and the second end 124 of the inductor are for example vertically aligned with a common portion of the two turns defining the eight, that is to say vertically aligned with joint end sections of the second turn 102 and the third turn 103. This advantageously facilitates the routing of the inductance 100 with external components, for example located in a lower level of the stack and at least partially overlapping with the inductance 100. For example, in a voltage-controlled oscillator, a bank of switched-capacitors is located below the inductance and is connected to the ends of the inductance. Another advantage is to bring the ends 123 and 124 closer together and to easily connect them to connection terminals located on the same side of the inductor and close to one another, for example to avoid an additional routing and lower the footprint of the inductance. Although this is not illustrated in the figures, the ends of the inductor are for example connected to connection terminals located on opposite sides of the inductor. The location of the ends enables a relatively high flexibility in the location of the connection terminals.

The midpoint of the inductor is located in the central region of the eight-shaped conductive track and is for example connected to the end 116 of track 108 that is located in level M1, at least partially overlapping the central region, for example vertically aligned with the central region. The midpoint therefore has the same advantages mentioned previously for the ends 123 and 124.

An advantage of the arrangement described in relation with FIGS. 1 to 4 is that it enables to limit the mutual parasitic inductance with neighboring components. This is due to the fact that part of the turns of the inductor, turns 101 and 102 in the shown example, conducts a current flowing in a first rotation direction, while another part of the turns of the inductor, turns 103 and 104 in the shown example, conducts a current flowing in a second rotation direction opposite to the first direction. The mutual parasitic inductance, as seen by neighboring components, is thus decreased, without for this to decrease the self-inductance value, which is linked to the total number of turns in the inductor.

As compared with a planar eight-shaped inductor arrangement, that is, in which all the turns of the inductor are mainly formed in a same conductive level, an additional advantage is to decrease the general bulk of the inductor.

Considering identical widths and thicknesses of conductive tracks, the arrangement described in relation with FIGS. 1 to 4 requires between 1.6 and 1.8 times less surface area than an inductor having a planar eight-shaped arrangement to obtain a substantially equal self-inductance. For example, the arrangement described in relation with FIGS. 1 to 4 enables to generate an inductance of approximately 0.8 nH on a general surface area in the order of 22,000 μm², to be compared with approximately 40,000 μm² with a planar eight-shaped arrangement. According to another example, the arrangement described in relation with FIGS. 1 to 4 enables to generate an inductance of approximately 1.1 nH over a general surface area in the order of 31,000 μm², to be compared with approximately 51,000 μm² for an inductor having a planar eight-shaped arrangement. According to another example, the arrangement described in relation with FIGS. 1 to 4 enables to generate an inductance of approximately 1.4 nH over a general surface area in the order of 38,000 μm², to be compared with approximately 63,000 μm² with a planar eight-shaped arrangement.

Another advantage of the embodiment described in relation with FIGS. 1 to 4 is that it allows the taking of a contact on the midpoint of the inductor, which enables to use the inductor in differential mode.

Inductors of the type described in relation with FIGS. 1 to 4 can advantageously be used many applications, for example in voltage-controlled oscillators (VCOs), for example in radio frequency signal synthesis applications, for example in radio telecommunication devices, for example cell phones. The decrease of the mutual parasitic inductance between the inductor and neighboring components then enables to synthesize more precise and stabler reference frequencies.

More generally, such inductors can be used in any circuit likely to take advantage of a decrease in the parasitic mutual inductance between the inductor and neighboring components.

Various embodiments and variants have been described. Those skilled in the art will understand that certain features of these various embodiments and variants may be combined, and other variants will occur to those skilled in the art. In particular, the described embodiments are not limited to the above-described example of an inductor with four turns formed in two conductive levels. More generally, those skilled in the art will be capable of adapting the provided solution to inductors with a number of turns greater than four and/or a number of conductive levels greater than two for the forming of the turns.

Further, the general shape of the turns of the inductor may be different from that shown. More generally, the turns of the inductor may have any other shape, for example a circular, square, rectangular, etc. general shape.

Further, the described embodiments are not limited to the specific example described in relation with FIGS. 1 to 4 in which the inductor comprises a connection terminal at its midpoint. As a variant, the connection terminal 125 at the midpoint 136 of the inductor may be omitted, in which case the inductor only comprises two connection terminals respectively connected to its two ends.

Finally, the practical implementation of the described embodiments and variants is within the abilities of those skilled in the art based on the functional indications given hereabove.

1. An inductor arranged in a stack of insulating and conductive levels, comprising:
in a first area of the stack, a first turn and a second turn respectively arranged in a first conductive level of the stack and in a second conductive level of the stack, the first conductive level and the second conductive level being distinct;
in a second area of the stack, at least a third turn and a fourth turn respectively arranged in the second conductive level and in the first conductive level; and
wherein the first turn, second turn, third turn, and fourth turn are series-connected between a first end and a second end of the inductor, so that a current applied between the first end and second end of the inductor flows in a first rotation direction in the first turn and second turn and in a second rotation direction opposite to the first direction in the third turn and fourth turn, wherein the second turn and the third turn are adjacent and define together an eight-shaped conductive track,
wherein the first turn and the second turn are overlapped, and
wherein the third turn and the fourth turn are overlapped.

2. The inductor of claim 1, wherein the first end and the second end of the inductor are at least partially overlapping a central region of the eight-shaped conductive track, the central region being comprised in the second turn and in the third turn.

3. The inductor of claim 1, wherein the first turn, second turn, third turn, and fourth turn are series-connected, in this order, between the first end and second end of the inductor.

4. The inductor of claim 1, wherein the first end of the inductor is connected to a first connection terminal of the inductor by at least one conductive track located in a third conductive level.

5. The inductor of claim 4, wherein the first connection terminal of the inductor is arranged in the first conductive level.

6. The inductor of claim 1, wherein the second end of the inductor is connected to a second connection terminal of the inductor by at least one conductive track located in a third conductive level.

7. The inductor of claim 6, wherein the second connection terminal of the inductor is arranged in the first conductive level.

8. The inductor of claim 1, wherein the midpoint of the inductor is connected to a third connection terminal of the inductor by at least one conductive track located in a third conductive level.

9. The inductor of claim 8, wherein the third connection terminal of the inductor is arranged in the first conductive level.

10. An integrated circuit comprising at least one inductor of claim 1.

11. A voltage-controlled oscillator comprising at least one inductor of claim 1.
